(19) United States
(12) Patent Application Publication
(10) Pub. No.: US 2023/0253193 A1
(43) Pub. Date: Aug. 10, 2023

(54) SUBSTRATE SUPPORT WITH UNIFORM TEMPERATURE ACROSS A SUBSTRATE

(71) Applicant: LAM RESEARCH CORPORATION, Fremont, CA (US)

(72) Inventors: Jeremy George SMITH, Oakland, CA (US); Alexander MATYUSHKIN, San Jose, CA (US); Eric SAMULON, Oakland, CA (US); Keith COMENDANT, Fremont, CA (US); Yixuan YU, Fremont, CA (US)

(21) Appl. No.: 18/013,768

(22) PCT Filed: Nov. 16, 2021
(86) PCT No.: PCT/US2021/059455

§ 371 Date: Dec. 29, 2022

Related U.S. Application Data
(60) Provisional application No. 63/115,988, filed on Nov. 19, 2020.

(51) Int. Cl. H01J 37/32; C23C 16/458; C23C 16/44

(52) U.S. Cl. CPC H01J 37/32724; C23C 16/4581; C23C 16/4404; H01J 2237/334; H01L 21/6833

(57) ABSTRACT

A substrate support for a substrate processing system includes a baseplate and a spray coat layer arranged on the baseplate. The spray coat layer has a first thickness and a first thermal conductivity. A bond layer is arranged on the spray coat layer. The bond layer has a second thickness and a second thermal conductivity. A ceramic layer is arranged on the bond layer. At least one of the first thickness and the second thickness varies in at least one of a radial direction and an azimuthal direction such that a third thermal conductivity between the ceramic layer and the baseplate varies in the at least one of the radial direction and the azimuthal direction.

### CROSS-REFERENCE TO RELATED APPLICATIONS

This application claims the benefit of U.S. Provisional Application No. 63/115,988, filed on Nov. 19, 2020. The entire disclosure of the application referenced above is incorporated herein by reference.

### FIELD

The present disclosure relates to controlling a temperature of a substrate in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, dielectric etch, and/or other etch, deposition, or cleaning processes. A substrate may be arranged on a substrate support, such as a pedestal, an electrostatic chuck (ESC), etc. in a processing chamber of the substrate processing system. During etching, etch gas mixtures including one or more gases may be introduced into the processing chamber and plasma may be used to initiate chemical reactions.

The substrate support may include a ceramic layer arranged to support a substrate. For example, the substrate may be clamped to the ceramic layer during processing. The substrate support may include a plurality of channels to provide a heat transfer gas (e.g., helium) to a backside of the substrate arranged on the ceramic layer. The heat transfer gas facilitates cooling of the substrate and/or the ceramic layer.

### SUMMARY

A substrate support for a substrate processing system includes a baseplate and a spray coat layer arranged on the baseplate. The spray coat layer has a first thickness and a first thermal conductivity. A bond layer is arranged on the spray coat layer. The bond layer has a second thickness and a second thermal conductivity. A ceramic layer is arranged on the bond layer. At least one of the first thickness and the second thickness varies in at least one of a radial direction and an azimuthal direction such that a third thermal conductivity between the ceramic layer and the baseplate varies in the at least one of the radial direction and the azimuthal direction.

In other features, the first thickness of the spray coat layer varies in the radial direction. The baseplate includes a recessed region and the spray coat layer is arranged in the recessed region. The first thickness of the spray coat layer is greater in the recessed region than in an outer edge region of the substrate support and the third thermal conductivity is greater in the outer edge region than in the recessed region. The spray coat layer comprises a first material in the recessed region and a second material different from the first material in the outer edge region.

In other features, each of the first thickness and the second thickness varies in the radial direction. The spray coat layer includes a recess region and each of the spray coat layer and the bond layer is arranged in the recessed region. The first thickness of the spray coat layer is greater in an outer edge region of the substrate support than in the recessed region, the second thickness of the bond layer is greater in the recessed region than in the outer edge region, and the third thermal conductivity is greater in the outer edge region than in the recessed region. The second thickness of the bond layer varies in the radial direction.

In other features, the ceramic layer includes a recessed region and the bond layer is arranged in the recessed region. The second thickness of the bond layer is greater in the recessed region than in an outer edge region of the substrate support and the third thermal conductivity is greater in the outer edge region than in the recessed region. The first thermal conductivity and the second thermal conductivity are different.

A substrate support for a substrate processing system includes a baseplate and a spray coat layer arranged on the baseplate. The spray coat layer has a first thickness and a first thermal conductivity. A bond layer is arranged on the spray coat layer. The bond layer has a second thickness and a second thermal conductivity. An outer bond layer is arranged on the spray coat layer radially outside of the bond layer. The outer bond layer has a third thermal conductivity different from the second thermal conductivity. A ceramic layer is arranged on the bond layer. A fourth thermal conductivity between the ceramic layer and the baseplate varies in a radial direction.

In other features, the third thermal conductivity is greater than the second thermal conductivity. The third thermal conductivity is at least 1.5 times greater than the second thermal conductivity.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing system according to the present disclosure;

FIG. 2A is a first example configuration of a substrate support according to the present disclosure;

FIG. 2B is a second example configuration of a substrate support according to the present disclosure;

FIG. 2C is a third example configuration of a substrate support according to the present disclosure;

FIG. 2D is a fourth example configuration of a substrate support according to the present disclosure;

FIG. 2E is a fifth example configuration of a substrate support according to the present disclosure;

FIG. 2F is a sixth example configuration of a substrate support according to the present disclosure;

FIG. 2G is a seventh example configuration of a substrate support according to the present disclosure; and

FIG. 3 is a plan view of an example substrate support according to the present disclosure.

In the drawings, reference numbers may be reused to identify similar and/or identical elements.

### DETAILED DESCRIPTION

In some substrate processing systems, a substrate support such as an electrostatic chuck (ESC) may be controlled (e.g., cooled) to maintain a desired substrate temperature. In some examples, the substrate support may dissipate as much as 30 kW of heat. Non-uniform heat dissipation (e.g., radial and azimuthal temperature non-uniformities) may cause process and substrate non-uniformities. For example, the substrate temperature may increase approximately 45° C. (e.g. +/−1° C.) in the presence of 6 kW plasma. Other non-uniformities (e.g., non-uniformities in a thermal stack of the substrate support, ion flux to a surface of the substrate, etc.) may cause temperatures across the substrate to vary (e.g., by 5-10° C.). However, a maximum variation of <1° C. may be desired.

In some examples, temperature variation across the substrate support and the substrate may be reduced by optimizing cooling channel patterns of the substrate support, optimizing characteristics (e.g., thickness) of a thermal bond layer provided between a baseplate and a ceramic layer of the substrate support, etc. However, available cooling channel patterns are limited by geometrical and other structural constraints of the baseplate, such as electrical connections, heat transfer gas channels, etc. Accordingly, substrate temperature variations significantly greater than 1° C. (e.g., (e.g., by 5-10° C.) may occur despite optimizing substrate support characteristics. In some examples, substrate temperature may be further controlled by adjusting resistive heaters and/or a pressure of a heat transfer gas supplied to the substrate support.

In some examples, temperatures in a region or zone corresponding to an outer perimeter or edge of the substrate may be greater than temperatures corresponding to an interior of the substrate. For example, the outer edge of the substrate may overlap an outer edge of the substrate support. In ESCs, the clamping of the substrate at the outer edge of the substrate support may change a plasma profile above the substrate, causing a difference in heat flux between the outer edge and an interior of the substrate support.

Substrate supports according to the present disclosure are configured to achieve desired temperature uniformities (e.g., radial and/or azimuthal uniformity) using various modifications of components such as a spray coat layer, a bond layer, a baseplate, and/or a ceramic layer. In some examples, the components may be modified to intentionally introduce thermal non-uniformities. The modifications may be implemented with or without other temperature control mechanisms (e.g., coolant channels, resistive heaters, heat transfer gas tuning, etc.).

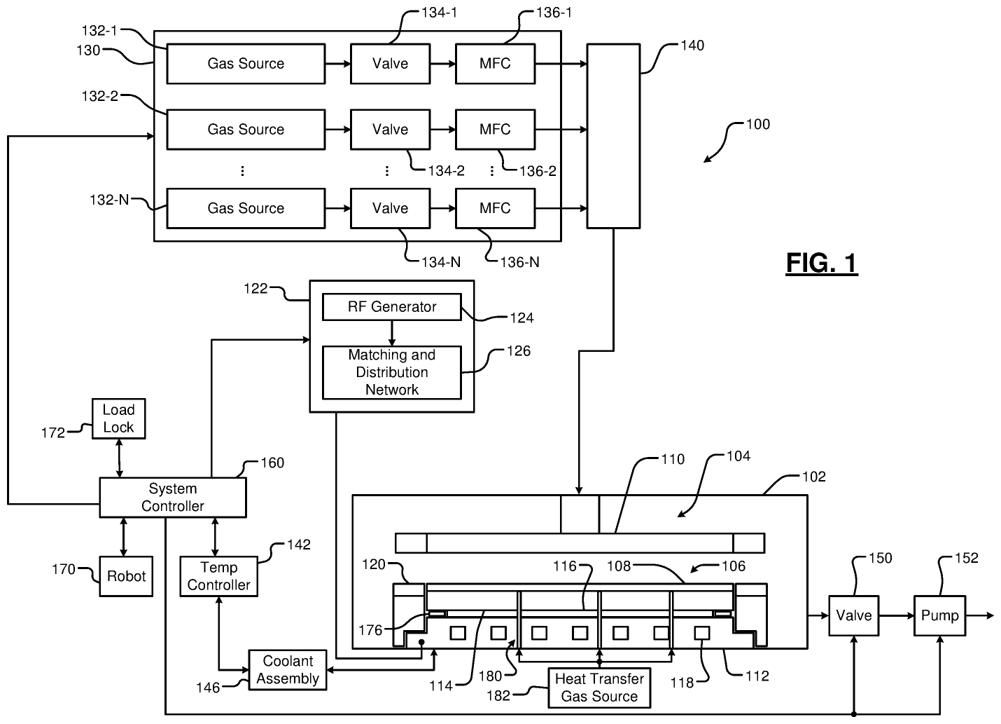

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an ESC. During operation, a substrate 108 is arranged on the substrate support 106. While a specific substrate processing system 100 and processing chamber 102 are shown as an example, the principles of the present disclosure may be applied to other types of substrate processing systems and processing chambers, such as a substrate processing system that generates plasma in-situ, implements remote plasma generation and delivery (e.g., using a plasma tube, a microwave tube), performs deposition, etc.

For example only, the upper electrode 104 may include a gas distribution device such as a showerhead 110 that introduces and distributes process gases. The showerhead 110 may include a stem portion including one end connected to a top surface of the processing chamber 102 and a base portion that is generally cylindrical and extends radially outwardly from an opposite end of the stem portion at a location that is spaced from a top surface of the processing chamber 102. A substrate-facing surface or faceplate of the base portion of the showerhead 110 includes a plurality of holes through which process gas or purge gas flows. Alternately, the upper electrode 104 may include a conducting plate and the process gases may be introduced in another manner.

The substrate support 106 includes a conductive baseplate 112 that acts as a lower electrode. The baseplate 112 supports a ceramic layer 114. A bond layer 116 may be arranged between the ceramic layer 114 and the baseplate 112. In some examples, a spray coat layer (not shown in FIG. 1) is arranged between the bond layer 116 and the baseplate 112. The baseplate 112 may include one or more coolant channels 118 for flowing coolant through the baseplate 112. The substrate support 106 may include an edge ring 120 arranged to surround an outer perimeter of the substrate 108.

An RF generating system 122 generates and outputs an RF voltage to one of the upper electrode 104 and the lower electrode (e.g., the baseplate 112 of the substrate support 106). The other one of the upper electrode 104 and the baseplate 112 may be DC grounded, AC grounded or floating. In the present example, the RF voltage is supplied to the lower electrode. For example only, the RF generating system 122 may include an RF voltage generator 124 that generates the RF voltage that is fed by a matching and distribution network 126 to the upper electrode 104 or the baseplate 112. In other examples, the plasma may be generated inductively or remotely. Although, as shown for example purposes, the RF generating system 122 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more etch gases and mixtures thereof. The gas sources may also supply carrier and/or purge gas. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 110.

A temperature controller 142 may communicate with a coolant assembly 146 to control coolant flow through the channels 118. For example, the coolant assembly 146 may include a coolant pump and reservoir. The temperature controller 142 operates the coolant assembly 146 to selectively flow the coolant through the channels 118 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160. In some examples, a protective seal 176 may be provided around a perimeter of the bond layer 116 between the ceramic layer 114 and the baseplate 112.

In some examples, the substrate support 106 includes a plurality of channels 180 arranged to provide a heat transfer gas such as helium from a heat transfer gas source 182 to a backside of the substrate 108. The heat transfer gas facilitates cooling of the substrate 108 and/or the ceramic layer 114. Although shown separately, the heat transfer gas source 182 may be implemented within the gas delivery system 130. Further, although the substrate support 106 is shown to include three of the channels 180 for simplicity, the substrate support 106 may include any number of the channels 180.

In the substrate support 106 according to the present disclosure, different configurations of the bond layer 116, the baseplate 112, the ceramic layer 114, and/or the spray coat layer are implemented to achieve desired temperature uniformities and/or to introduce desired temperature non-uniformities as described below in more detail.

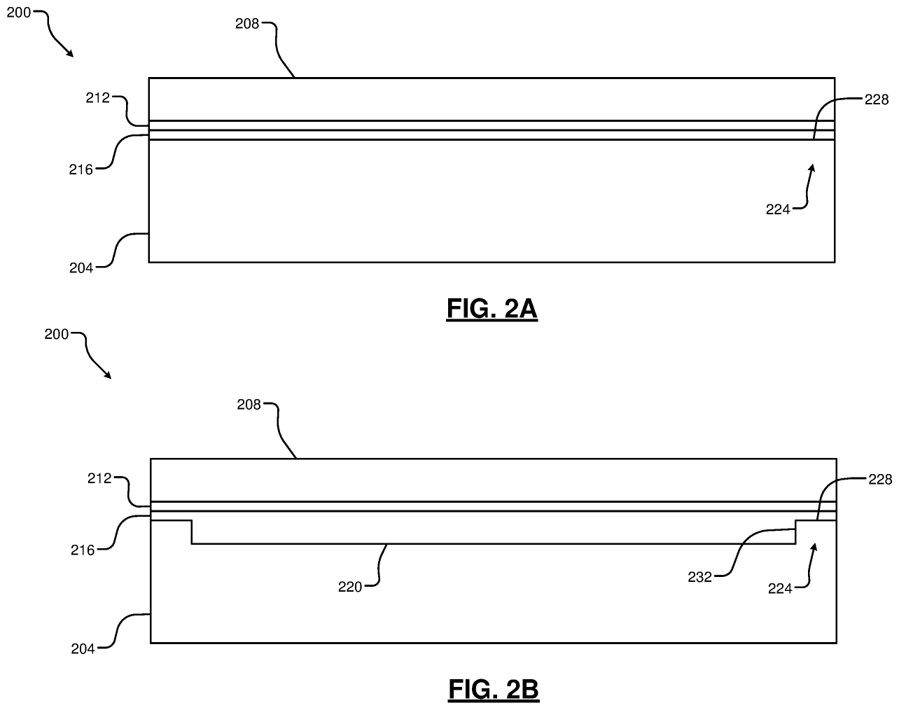

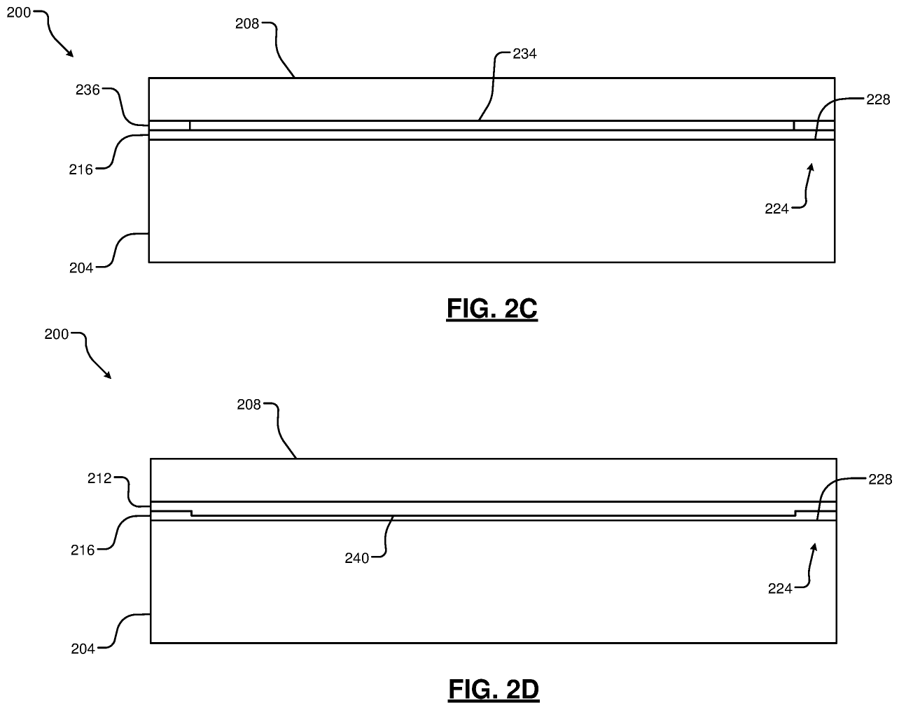

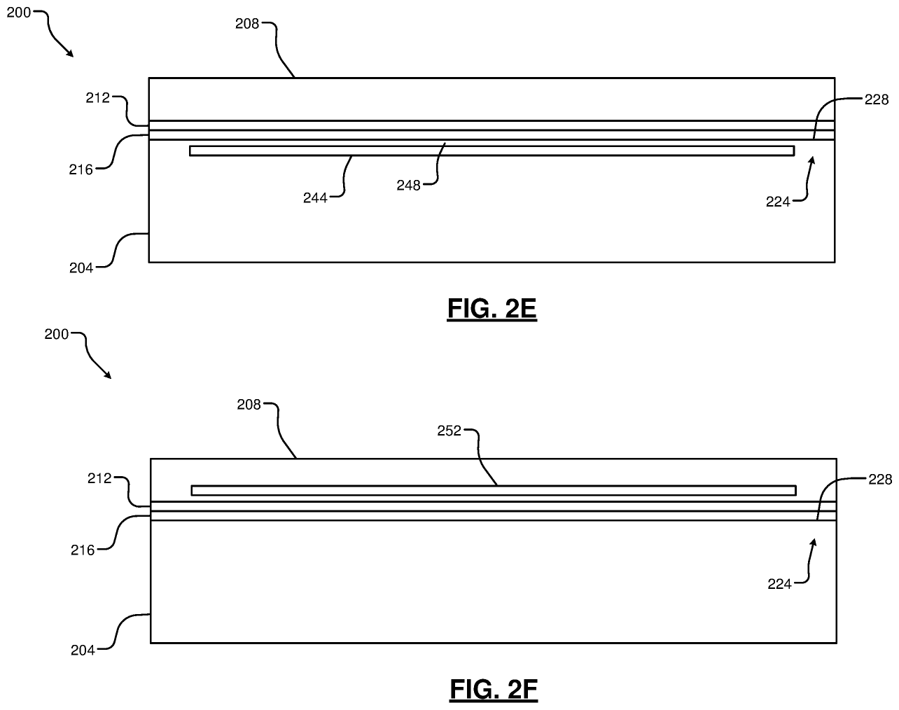

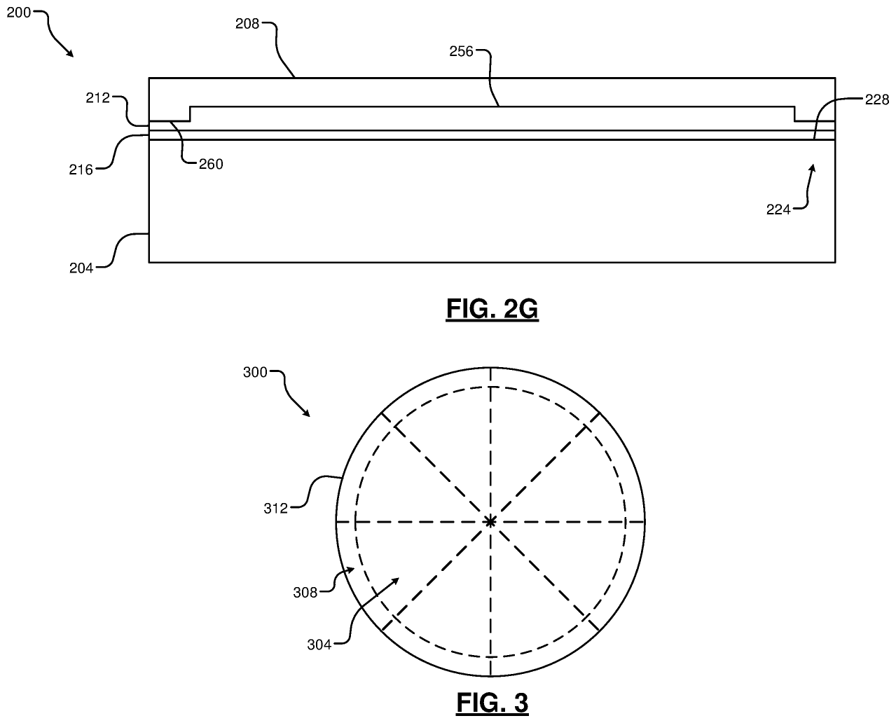

Example configurations of substrate supports 200 according to the principles of the present disclosure are shown in FIGS. 2A, 2B, 2C, 2D, 2E, 2F, and 2G. As shown in FIG. 2A, the substrate support 200 includes a conductive (e.g., aluminum) baseplate 204 supporting a ceramic layer 208. A bond layer 212 and a spray coat layer 216 are arranged between the baseplate 204 and the ceramic layer 208. For example, the spray coat layer 216 is arranged on the baseplate 204 and the bond layer 212 is arranged on the spray coat layer 216.

The bond layer 212 and the spray coat layer 216 may have same or different thicknesses and may have same or different thermal conductivities (i.e., thermal conductivity values, such as k coefficients or values (W/mK)). For example, the bond layer 212 includes a thermal adhesive, such as a thermal epoxy, silicone, etc. The spray coat layer 216 is a material deposited using spray coat methods, such as aluminum oxide (AlO₂), yttria (e.g., yttrium oxide (Y₂O₃)), etc. Each of the bond layer 212 and the spray coat layer 216 may have thermal conductivities less than a thermal conductivity of the baseplate 204.

As shown in FIG. 2A, respective thicknesses of the bond layer 212 and the spray coat layer 216 do not vary (i.e., are uniform) across the substrate support 200. In other words, the thicknesses of the bond layer 212 and the spray coat layer 216 do not vary in radial or azimuthal directions. In other examples, relative thicknesses of the bond layer 212 and the spray coat layer 216 may vary in the radial and/or azimuthal (i.e., rotational) directions.

As shown in FIG. 2B, the baseplate 204 is stepped and includes a cutout or recessed region 220. The spray coat layer 216 is arranged in and fills the recessed region 220. Accordingly, distance and thermal conductivity between the ceramic layer 208 and the baseplate 204 are different in a region of the substrate support 200 corresponding to the recessed region 220 than in an outer edge region 224 of the substrate support 200. In this manner, the substrate support 200 can be configured to have different thermal conductivities in different radial regions to compensate for thermal non-uniformities. For example, because a thickness of the spray coat layer 216 in the outer edge region 224 is less than (e.g., 25-75% of) a thickness of the spray coat layer 216 in the recessed region 220, a thermal conductivity in the edge region 224 is greater than a thermal conductivity in the recessed region 220. In other examples, the recessed region 220 may be filled with a different material instead of the spray coat layer 216. For example, a hard polymer (e.g., polyimide) may be arranged in the recessed region 220.

Although as shown the baseplate 204 has only one step downward from an upper surface 228 to the recessed region 220, in other examples the baseplate 204 may have two or more steps downward to define multiple recessed regions. In other words, the recessed region 220 may have multiple depths. In some examples, the baseplate 204 may include multiple radial recessed regions 220. Further, sidewalls 232 of the recessed region 220 may be sloped or curvilinear instead of vertical (as shown). In other examples, the recessed region 220 may correspond to the outer edge region 224. In other words, the baseplate 204 may step downward in the outer edge region 224. In some examples, the spray coat layer 216 includes a different material (e.g., a material having a different thermal conductivity) in the recessed region 220 than in the outer edge region 224.

As shown in FIG. 2C, the substrate support 200 includes an inner bond layer 234 and an outer bond layer 236 arranged radially outside of the inner bond layer 234. The outer bond layer 236 has a different thermal conductivity than the inner bond layer 234 (e.g., the outer bond layer 236 is comprised of a different material or mixture of materials than the inner bond layer 234). For example, the thermal conductivity of the outer bond layer 236 is greater than the thermal conductivity of the inner bond layer 234. In some examples, the thermal conductivity of the outer bond layer 236 is 1.5 to 5 times greater than the thermal conductivity of the inner bond layer 234. In other examples, the thermal conductivity of the inner bond layer 234 is greater than the thermal conductivity of the outer bond layer 236. In this manner, the outer bond layer 236 provides a different thermal conductivity in the outer edge region 224 to compensate for thermal non-uniformities.

One or both of the inner bond layer 234 and the outer bond layer 236 may be fully or partially pre-cured prior to being arranged on the spray coat layer 216 to prevent mixing of the respective materials of the inner bond layer 234 and the outer bond layer 236. For example, the outer bond layer 236 may be pre-cured and arranged on the spray coat layer 216 prior to applying the inner bond layer 234. In other examples, the inner bond layer 234 and/or the outer bond layer 236 are applied using screen printing, sheet bonding, etc. In some examples, a dam or barrier (e.g., comprised of pre-cured bond material) may be arranged on the spray coat layer 216 to define separate regions prior to applying the inner bond layer 234 and the outer bond layer 236.

Although as shown the substrate support 200 includes only the inner bond layer 234 and the outer bond layer 236 (i.e., two bond layers), in other examples the substrate support 200 may have three or more of the bond layers having same or different thermal conductivities arranged in respective radial regions. In some examples, the bond layers in the respective radial regions may be separated by a barrier as described above.

As shown in FIG. 2D, the spray coat layer 216 is stepped and includes a cutout or recessed region 240. The bond layer 212 is arranged in and fills the recessed region 240. Accordingly, thermal conductivity between the ceramic layer 208 and the baseplate 204 are different in a region of the substrate support 200 corresponding to the recessed region 240 than in the outer edge region 224 of the substrate support 200. For example, thermal conductivities of the bond layer 212 and the spray coat layer 216 may be different. In some examples, the thermal conductivity of the bond layer 212 is less than the thermal conductivity of the spray coat layer 216. Accordingly, increasing a thickness of the bond layer 212 in the recessed region 240 (e.g., by 25-200%) decreases the thermal conductivity in the recessed region 240 relative to the outer edge region 224.

Although as shown the spray coat layer 216 has only one step downward to the recessed region 240, in other examples the spray coat layer 216 may have two or more steps downward to define multiple recessed regions. In other words, the recessed region 240 may have multiple depths. Further, sidewalls of the recessed region 240 may be sloped or curvilinear instead of vertical (as shown). In other examples, the recessed region 240 may correspond to the outer edge region 224. In other words, the spray coat layer 216 may step downward in the outer edge region 224. In examples where the recessed region 240 corresponds to the outer edge region 224, the thermal conductivity of the bond layer 212 may be greater than the thermal conductivity of the spray coat layer 216. Accordingly, increasing the thickness of the bond layer 212 relative to the spray coat layer 216 in the outer edge region 224 increases the thermal conductivity in the outer edge region 224. In some examples, the spray coat layer 216 and/or the bond layer 212 includes a different material (e.g., a material having a different thermal conductivity) in the recessed region 240 than in the outer edge region 224.

As shown in FIG. 2E, the baseplate 204 may define a plenum or cavity 244 below the upper surface 228. In other words, the cavity 244 is embedded within the baseplate 204. For example, the cavity 244 may be machined into the upper surface 228 of the baseplate 204 and a metal layer (e.g., a braze layer comprising a same material as the baseplate 204) 248 is arranged to enclose the cavity 244. The cavity 244 is filled with a material having a different thermal conductivity than the baseplate 204. For example, the cavity 244 may be pumped down to vacuum, filled with air or heat transfer gas, filled with bond material, filled with a hard plastic such as polyimide, etc. Accordingly, thermal conductivity in a region corresponding to the cavity 244 is reduced relative to the outer edge region 224.

Although as shown the baseplate 204 has only one cavity 244 in a radially inner region of the substrate support 200, in other examples the baseplate 204 may have two or more of the cavities 244. For example, the baseplate 204 may include multiple radial cavities having same or different thicknesses and depths. In other examples, the cavity 244 may be arranged in the outer edge region 224.

As shown in FIG. 2F, the ceramic layer 208 may define a plenum or cavity 252. In other words, the cavity 252 is embedded within the ceramic layer 208. For example, the cavity 252 may be formed during manufacture of the ceramic layer 208 (e.g., while layering green sheets). The cavity 252 is filled with a material having a different thermal conductivity than the ceramic layer 208. For example, the cavity 252 may be pumped down to vacuum, filled with air or heat transfer gas, filled with bond material, filled with a hard plastic such as polyimide, etc. Accordingly, thermal conductivity in a region corresponding to the cavity 244 is reduced relative to the outer edge region 224. Although as shown the ceramic layer 208 has only one cavity 252 in a radially inner region of the substrate support 200, in other examples the ceramic layer 208 may have two or more of the cavities 252. For example, the ceramic layer 208 may include multiple radial cavities having same or different thicknesses and depths. In other examples, the cavity 252 may be arranged in the outer edge region 224.

As shown in FIG. 2G, the ceramic layer 208 is stepped and includes a cutout or recessed region 256. The bond layer 212 is arranged in and fills the recessed region 256. Accordingly, thermal conductivity between the ceramic layer 208 and the baseplate 204 are different in a region of the substrate support 200 corresponding to the recessed region 256 than in an outer edge region 224 of the substrate support 200. For example, because a thickness of the bond layer 212 in the outer edge region 224 is less than a thickness of the bond layer 212 in the recessed region 256, a thermal conductivity in the edge region 224 is greater than a thermal conductivity in the recessed region 256. In other examples, the recessed region 256 may be filled with a different material instead of the bond layer 212. For example, a hard polymer (e.g., polyimide) may be arranged in the recessed region 256.

Although as shown the ceramic layer 208 has only one step upward from a lower surface 260 to the recessed region 256, in other examples the ceramic layer 208 may have two or more steps upward to define multiple recessed regions. In other words, the recessed region 256 may have multiple depths. In some examples, the ceramic layer 208 may include multiple radial recessed regions 256. In other examples, the recessed region 256 may correspond to the outer edge region 224. In other words, the ceramic layer 208 may step upward in the outer edge region 224. In some examples, the bond layer 212 includes a different material (e.g., a material having a different thermal conductivity) in the recessed region 256 than in the outer edge region 224.

As described above in FIGS. 2A-2G, the substrate support 200 is configured to provide different thermal conductivities in a radial direction (e.g., in different radial regions or zones). For example, the substrate support 200 is configured to provide a different (e.g., greater) thermal conductivity in the outer edge region 224 than an inner region of the substrate support 200. However, the same principles described in FIGS. 2A-2G may also be implemented to provide different thermal conductivities in an azimuthal direction (e.g., in different azimuthal regions or zones) of the substrate support 204 in addition to or instead of in different radial regions.

Referring now to FIG. 3 and with continued reference to FIGS. 2A-2G, a plan view of an example substrate support 300 is shown having a plurality of radial zones (e.g., an inner zone 304 and an outer edge zone 308 and a plurality of azimuthal zones 312. Although only two of the radial zones are shown, the substrate support 300 may include more than two radial zones. Similarly, although eight of the azimuthal zones 312 are shown, the substrate support 300 may include fewer or more than eight of the azimuthal zones 312. Further, although the azimuthal zones 312 are shown having generally uniform size and shape, the azimuthal zones 312 may be non-uniform.

As described above in FIGS. 2A-2G, relative thicknesses and thermal conductivities of various components of the substrate support 200 (e.g., the baseplate 204, the ceramic layer 208, the bond layer 212, the spray coat layer 216, etc.) are modified to adjust relative thermal conductivities in the inner zone 304 and the outer edge zone 308. As shown in FIG. 3, the same principles may be applied to these components to adjust relative thermal conductivities in the azimuthal zones 312.

For example, the baseplate 204 may include the recessed region 220 as described in FIG. 2B only in selected ones of the azimuthal zones 312, or the recessed region 220 may have different depths in different ones of the azimuthal zones 312. The outer bond layer 236 (e.g., as described in FIG. 2C) may be provided in only selected ones of the azimuthal zones 312, or different materials may be used for the outer bond layer 236 in different ones of the azimuthal zones. The spray coat layer 216 may include a recessed region 240 (e.g., as described in FIG. 2D) in only selected ones of the azimuthal zones 312, or the recessed region 240 may have different depths in different ones of the azimuthal zones 312.

The cavity 244 (e.g., in the baseplate 204 as described in FIG. 2E) may be provided in only selected ones of the azimuthal zones 312, or may have different depths or be filled with different materials in different ones of the azimuthal zones 312. The cavity 252 (e.g., in the ceramic layer 208 as described in FIG. 2F) may be provided in only selected ones of the azimuthal zones 312, or may have different depths or be filled with different materials in different ones of the azimuthal zones 312. The ceramic layer 208 may include the recessed region 256 as described in FIG. 2G only in selected ones of the azimuthal zones 312, or the recessed region 256 may have different depths in different ones of the azimuthal zones 312.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support for a substrate processing system, the substrate support comprising:
a baseplate;
a spray coat layer arranged on the baseplate, wherein the spray coat layer has a first thickness and a first thermal conductivity;
a bond layer arranged on the spray coat layer, wherein the bond layer has a second thickness and a second thermal conductivity; and
a ceramic layer arranged on the bond layer,
wherein at least one of the first thickness and the second thickness varies in at least one of a radial direction and an azimuthal direction such that a third thermal conductivity between the ceramic layer and the baseplate varies in the at least one of the radial direction and the azimuthal direction.

2. The substrate support of claim 1, wherein the first thickness of the spray coat layer varies in the radial direction.

3. The substrate support of claim 2, wherein the baseplate includes a recessed region and the spray coat layer is arranged in the recessed region.

4. The substrate support of claim 3, wherein (i) the first thickness of the spray coat layer is greater in the recessed region than in an outer edge region of the substrate support and (ii) the third thermal conductivity is greater in the outer edge region than in the recessed region.

5. The substrate support of claim 4, wherein the spray coat layer comprises a first material in the recessed region and a second material different from the first material in the outer edge region.

6. The substrate support of claim 1, wherein each of the first thickness and the second thickness varies in the radial direction.

7. The substrate support of claim 6, wherein the spray coat layer includes a recess region and each of the spray coat layer and the bond layer is arranged in the recessed region.

8. The substrate support of claim 7, wherein (i) the first thickness of the spray coat layer is greater in an outer edge region of the substrate support than in the recessed region, (ii) the second thickness of the bond layer is greater in the recessed region than in the outer edge region, and (iii) the third thermal conductivity is greater in the outer edge region than in the recessed region.

9. The substrate support of claim 1, wherein the second thickness of the bond layer varies in the radial direction.

10. The substrate support of claim 9, wherein the ceramic layer includes a recessed region and the bond layer is arranged in the recessed region.

11. The substrate support of claim 10, wherein (i) the second thickness of the bond layer is greater in the recessed region than in an outer edge region of the substrate support and (ii) the third thermal conductivity is greater in the outer edge region than in the recessed region.

12. The substrate support of claim 1, wherein the first thermal conductivity and the second thermal conductivity are different.

13. A substrate support for a substrate processing system, the substrate support comprising:
a baseplate;
a spray coat layer arranged on the baseplate, wherein the spray coat layer has a first thickness and a first thermal conductivity;
a bond layer arranged on the spray coat layer, wherein the bond layer has a second thickness and a second thermal conductivity;
an outer bond layer arranged on the spray coat layer radially outside of the bond layer, wherein the outer bond layer has a third thermal conductivity different from the second thermal conductivity; and
a ceramic layer arranged on the bond layer,
wherein a fourth thermal conductivity between the ceramic layer and the baseplate varies in a radial direction.

14. The substrate support of claim 13, wherein the third thermal conductivity is greater than the second thermal conductivity.

15. The substrate support of claim 14, wherein the third thermal conductivity is at least 1.5 times greater than the second thermal conductivity.

16. A substrate support for a substrate processing system, the substrate support comprising:
a baseplate;
a spray coat layer arranged on the baseplate, wherein the spray coat layer has a first thickness and a first thermal conductivity;
a bond layer arranged on the spray coat layer, wherein the bond layer has a second thickness and a second thermal conductivity;
a ceramic layer arranged on the bond layer; and
a cavity defined within at least one of the baseplate and the ceramic layer,
wherein the cavity encloses one of vacuum, air, and a heat transfer gas such that a third thermal conductivity between the ceramic layer and the baseplate varies in the at least one of a radial direction and an azimuthal direction.

17. The substrate support of claim 16, wherein the baseplate includes the cavity.

18. The substrate support of claim 16, wherein the ceramic layer includes the cavity.

19. The substrate support of claim 16, wherein the cavity is arranged in a radially inner region of the substrate support.

20. The substrate support of claim 16, wherein the third thermal conductivity is greater in an outer edge region of the substrate support than in an inner region of the substrate support.
